(19) United States
(12) Patent Application Publication
(10) Pub. No.: US 2025/0124197 A1
(43) Pub. Date: Apr. 17, 2025

(54) STORAGE MEDIUM STORED WITH MOLECULAR DYNAMICS COMPUTATION PROGRAM, MOLECULAR DYNAMICS COMPUTATION METHOD AND DEVICE

(71) Applicants: Fujitsu Limited, Kawasaki-shi (JP); RIKEN, Wako-shi (JP)

(72) Inventors: Shingo OKUNO, Kyoto (JP); Yusuke NAGASAKA, Kawasaki (JP); Ryo KANADA, Wako (JP); Atsushi TOKUHISA, Wako (JP); Shuntaro CHIBA, Wako (JP)

(73) Assignees: Fujitsu Limited, Kawasaki-shi (JP); RIKEN, Wako-shi (JP)

(21) Appl. No.: 18/908,845

(22) Filed: Oct. 8, 2024

(30) Foreign Application Priority Data
Oct. 13, 2023 (JP) 2023-177805

(51) Int. Cl. G06F 30/27

(52) U.S. Cl. CPC G06F 30/27

(57) ABSTRACT

A molecular dynamics computation device includes a processor that executes a procedure. The procedure includes: executing machine learning of a first force field for predicting energy for an input structure using, as training data, a structure of a coarse-grained model resulting from coarse-graining an all-atom model sampled by molecular dynamics computation based on an all-atom force field and an energy corresponding to the all-atom model structure; and computing molecular dynamics of a coarse-grained model based on a second force field obtained by combining the first force field that has been subjected to machine learning and an energy based on a coarse-grained model structure.

### CROSS-REFERENCE TO RELATED APPLICATION

This application claims the benefit of priority of the prior Japanese Patent Application No. 2023-177805, filed on Oct. 13, 2023, the entire contents of which are incorporated herein by reference.

### FIELD

The embodiments discussed herein are related to a storage medium stored with a molecular dynamics computation program, a molecular dynamics computation method, and a molecular dynamics computation device.

### BACKGROUND

Hitherto, simulations have been performed of the movements of atoms and molecules using molecular dynamics. For example, there is a proposal for an analysis method to analyze composite materials with a computer using molecular dynamics and to appropriately reproduce the behavior of a particle model inside an analysis model. In this analysis method, a machine learning model including a particle model for training modeling a substance in a composite material is employed to perform computation of behavior using molecular dynamics, and machine learning is performed on a prediction module using training data including at least information about positions in the particle model for training before and after lapse of a specific period of time. Such a prediction module takes a particle model for use in analysis from out of analysis models for composite materials as a particles-of-interest model, and predicts information about positions in the particles-of-interest model after lapse of a specific period of time using information about the relative positions in a neighboring-particles model, at the periphery of the particles-of-interest model, with respect to the particles-of-interest model. Information about the positions in the particles-of-interest model is found thereby. In the prediction by the prediction module, a prediction module is prepared separately for a first analysis particles model and a second analysis particles model that respectively model first and second substances in the composite materials.

There is also a proposal, for example, for a polymer material interaction potential determination method for deciding an interaction potential allowing a high accuracy simulation to be performed. In such a determination method, an all-atom filler model that models a filler with an all-atom model is set, and an all-atom polymer model that models molecule chains with an all-atom model is set so as to adjoin the all-atom filler model across a first interface. In this method, a structural relaxation of the all-atom filler model and the all-atom polymer model is computed based on molecular dynamics computation and a first interaction energy is found at the first interface between the all-atom filler model and the all-atom polymer model. Then based on the first interaction energy, an interaction parameter is determined that indicates strength of interaction potential at the interface between the filler and a molecule chain.

### Related Documents

### Related Patent Documents

Japanese Patent Application Laid-Open (JP-A) No. 2021-71803 JP-A No. 2020-42434.

### SUMMARY

According to an aspect of the embodiments, a non-transitory recording medium storing a program that is executable by a computer to perform a molecular dynamics computation process includes: executing machine learning of a first force field for predicting energy for an input structure using, as training data, a structure of a coarse-grained model resulting from coarse-graining an all-atom model sampled by molecular dynamics computation based on an all-atom force field and an energy corresponding to the all-atom model structure; and computing molecular dynamics of a coarse-grained model based on a second force field that combines the first force field that has been subjected to machine learning by combining with an energy based on a coarse-grained model structure.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram schematically illustrating an energy profile in related all-atom molecular dynamics (AA-MD).

FIG. 2 is a diagram schematically illustrating an energy profile in related coarse-grained molecular dynamics (CG-MD).

FIG. 3 is a diagram to explain related CG-MD.

FIG. 4 is a functional block diagram of a molecular dynamics computation device.

FIG. 5 is a diagram to explain energy minimization processing.

FIG. 6 is a diagram to explain energy averaging processing.

FIG. 7 is a diagram illustrating an example of a machine learning model configuring an artificial intelligence (AI) force field.

FIG. 8 is a block diagram illustrating a schematic configuration of a computer that functions as a molecular dynamics computation device.

FIG. 9 is a flowchart illustrating an example of molecular dynamics computation processing.

FIG. 10 is a diagram to explain advantageous effects of the present exemplary embodiment.

FIG. 11 is a diagram illustrating an example of structures sampled in the present exemplary embodiment.

FIG. 12 is a diagram to explain advantageous effects of the present exemplary embodiment.

### DESCRIPTION OF EMBODIMENTS

Explanation follows regarding an example of an exemplary embodiment according to technology disclosed herein, with reference to the drawings.

First, prior to giving a detailed description of the present exemplary embodiment, general issues that arise with AA-MD and CG-MD will be described.

First, molecular dynamics is the computation of various forces acting between atoms, such as bonding forces, intermolecular forces, electrostatic interactions, and the like, and is the computation (simulation) of movement of atoms and molecules based on these computed forces and on equations of motion by repeating processing to update the positions of each atom in a time evolution.

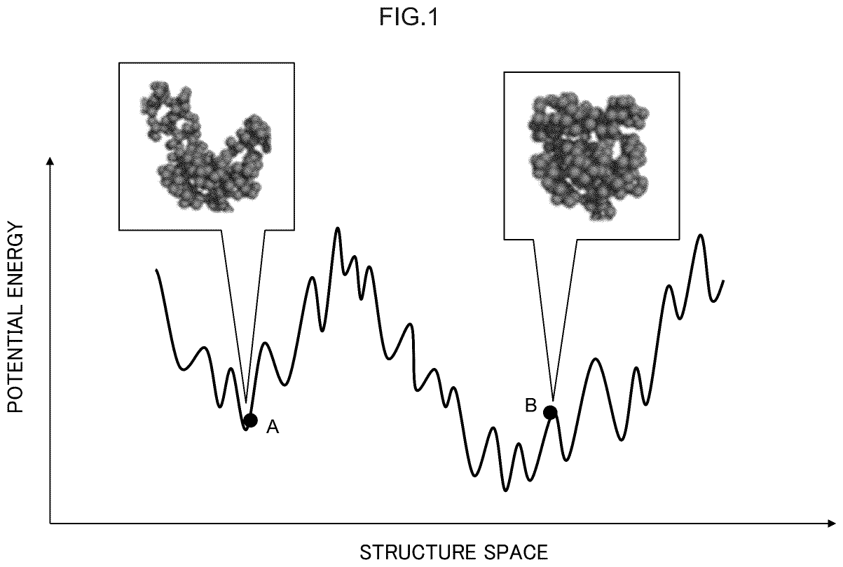

For example, in the field of drug discovery, there is a need to analyze a functional expression mechanism, structure change dynamics, and the like of a target protein in vivo. These analyzes are accordingly performed by executing AA-MD input with consideration of all atoms configuring a biomolecule. However, there are a huge number of degrees of freedom in AA-MD, and the computation cost to execute AA-MD is high, making it difficult to execute AA-MD for a long period of time (in the order of milliseconds, for example). Moreover, as illustrated in FIG. 1, in an all-atom force field, there are steep undulations in potential energy profile with respect to structure space of molecular structures, with many local minimum being present therein. This means that AA-MD often gets stuck in fine fluctuations trapped at a local minimum. Therefore, there is a need for a high computation cost to reproduce global structural changes that are probabilistically rare events using AA-MD such as, for example, to-and-fro between the state A and the state B as illustrated in FIG. 1.

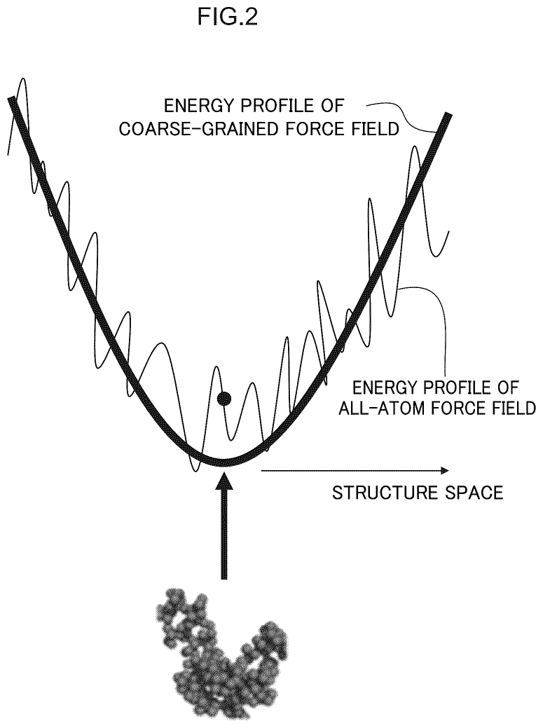

Thus, an all-atom model, in which a particle represents a single atom, is expressed by a coarse-grained model in which plural atoms are united as specific units represented by a single particle. Molecular dynamics computation is able to be executed over a long time at low computational cost using CG-MD, in which molecular dynamics are computed using a coarse-grained model. Moreover, although the computed energy profile (potential) of a coarse-grain force field is, for example, as illustrated in FIG. 2, smoother than the energy profile for an all-atom force field, there is not always a state of high correlation when compared to the all-atom energy profile. Although the coarse-grained force field energy profile is accordingly an energy profile including some arbitrariness, fluctuations around a reference structure can be quantitatively reproduced by adjusting relevant parameters.

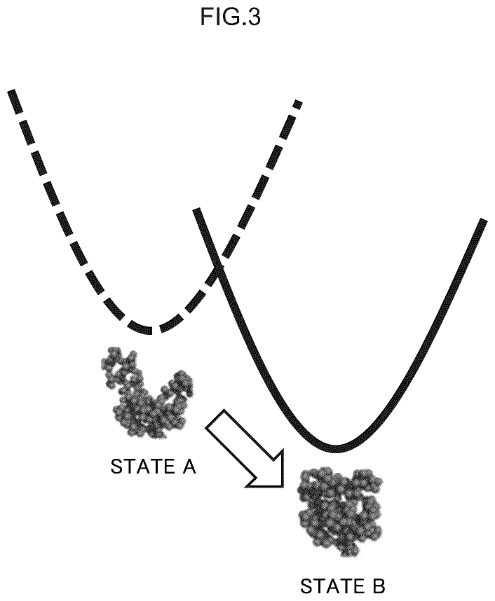

For example, as illustrated in FIG. 3, in cases in which the two structures of state A and state B are obtained by experimentation, the manner in which a global structural change takes place from the state A to the state B can be reproduced quickly and at low computation cost using CG-MD by relying on these two structures.

However, there is an issue with CG-MD in that reference structures obtained by experimentation or the like are strongly stabilized and sampled structures are constrained to the reference structures. More specifically, there is an issue that dynamics obtained with CG-MD are based on a force field having a high degree of arbitrariness originating from the reference structures, and are inferior compared to those of AA-MD. For example, in the example of FIG. 3, we assume that only the structure of state A is obtainable by experimentation, and the structure of state B is not obtainable thereby. In such cases, only peripheral structures to state A can be sampled using CG-MD, and a structural change from state A to state B is not able to be reproduced. Moreover, there is an issue in that the energy prediction accuracy with CG-MD is inferior compared to with AA-MD.

Thus, an object of the present exemplary embodiment is to reproduce global structural changes with good efficiency by efficient sampling of diverse structures, by executing CG-MD based on a force field that incorporates an AI force field that has been subjected to machine learning based on an all-atom model. Detailed description follows regarding the present exemplary embodiment.

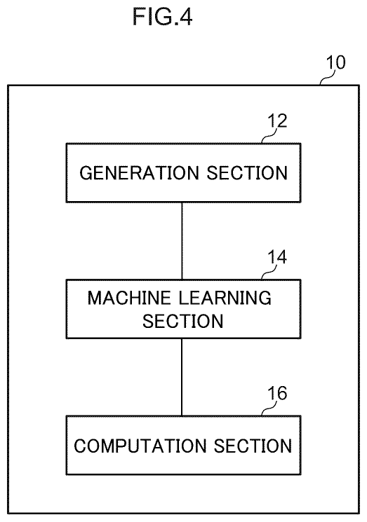

As illustrated in FIG. 4, a molecular dynamics computation device 10 includes, from a functional perspective, a generation section 12, a machine learning section 14, and a computation section 16.

The generation section 12 generates training data including a structure of a coarse-grained model resulting from coarse-graining an all-atom model sampled by computing molecular dynamics based on an all-atom force field, and including an energy corresponding to the structure of the all-atom model.

Specifically, the generation section 12 executes AA-MD and takes plural samplings of structures of an all-atom model and energies corresponding to these structures. Examples of AA-MD methods that may be employed include, for example, multicanonical molecular dynamics (McMD), replica exchange molecular dynamics (REMD), metadynamics, and the like, either employed singly or in a combination thereof.

Moreover, the generation section 12 may perform, on the structures and energies obtained by AA-MD, at least one correction selected from the group consisting of correction to stabilize energy, correction to minimize energy, and correction to average energy.

Description follows regarding an example of correction to stabilize energy. Structural ensembles sampled at high temperature using an enhanced sampling method such as REMD, McMD, or the like are diverse, however sometimes there are probabilistic breaks in the behavior, for example bond length or the like, of local structures that a protein should ordinarily hold, and an instability in energy. In order to address this, the generation section 12 may execute short MD equilibration processing, which is processing with the objective of energy stabilization, to settle, or to relax, the main chain of a sampled structure.

For example, the generation section 12 executes short MD equilibration processing of 500 ps under room temperature conditions (T=300K). Moreover, the generation section 12 may use software such as Amber or the like to execute short MD equilibration processing based on a water free (implicit-solvent) generalized born (GB) force field with the objective of suppressing computational cost and relaxing the structure.

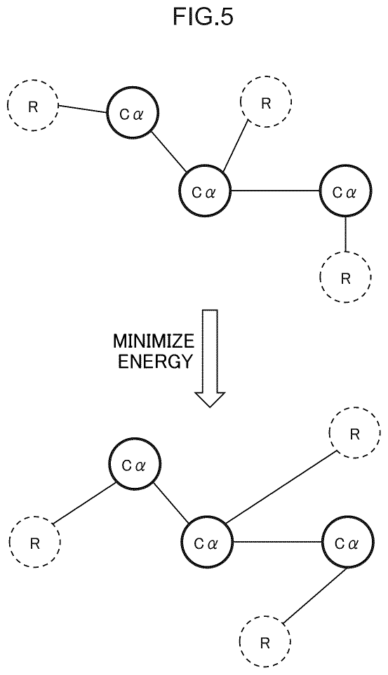

Next, description follows regarding an example of correction to minimize energy. The generation section 12 performs energy minimization processing with the main chain fixed. For example, as illustrated in FIG. 5, the generation section 12 fixes a protein main chain (Cα positions) and minimizes energy while only moving amino acid side chain portions. The generation section 12 may, for example, perform energy minimization processing using software such as GROMACS or the like.

In consideration of the need to perform such energy minimization, a coarse-grained model that has been coarse-grained to Cα atom units for each residue is applied in the present exemplary embodiment. Feature values extracted from the coarse-grained model structure are input during machine learning of the AI force field. In other words, training is performed while focusing only on the Cα atoms of the coarse-grained model structure.

When this is being performed, sometimes side chain positions differ greatly even if the main chain (Cα positions) is the same within a group of training structures. In such cases, a teacher energy (all-atom energy) held by a target protein is different for each of the structures. However, in the all-atom model, even if the side chain positions are different, as long as the main chain is the same, then this results in the same coarse-grained model structure. This means that there is a lack of consistency as training data in cases in which associated energies are different even though there is the same structure after being coarse-grained, and this lack of consistency is difficult to handle. Thus, energy minimization is performed such as described above in order to secure consistency of training data.

Next, description follows regarding an example of correction to average energy. As described above, the present exemplary embodiment focusses only on the Cα atoms of the coarse-grained model structure. Thus, with the objective of suppressing variation in energies generated by side chain structures, the generation section 12 averages training data so as to facilitate machine learning of correspondence relationships between Cα atom coordinates and energy values. Sufficient accuracy is thereby secured in MD even with a coarse-grained force field.

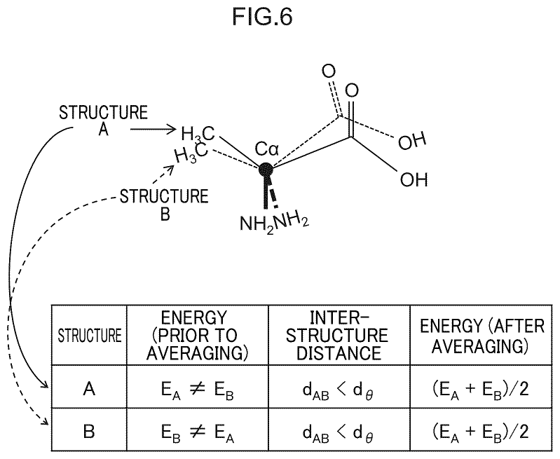

Specifically, the generation section 12 averages such that energies between like structures approach each other. For example as illustrated in FIG. 6, take the energy of structure A prior to averaging as E_{A}, and the energy of structure B prior to averaging as E_{B}. The generation section 12 computes an inter-structure distance d_{AB} between structure A and structure B. The inter-structure distance may, for example, be a root mean square deviation (RMSD). In cases in which the inter-structure distance d_{AB} is smaller than a threshold de, an average (E_{A}+E_{B})/2 of the energies of the structure A and structure B prior to averaging is taken as the post averaging energy for structure A and for structure B.

Moreover, the generation section 12 computes an energy value E_{AI} as training data according to following Equation (1).

$${E}_{AI} = {E}_{GB} - {E}_{stab} \qquad ( 1 )$$

E_{GB} of Equation (1) is an all-atom potential energy based on a generalized born (GB) model, and is the energy after the above correction. E_{stab} is a structure stabilization energy and is, for example, configured including part or all of the following four types of energy.
Interaction energy related to bond length: E_{bl} (see following Equation (2)).
Interaction energy related to bond angle: E_{ba} (see following Equation (3)).
Interaction energy related to dihedral angle: E_{da} (see following Equation (4)).
Interaction energy related to excluded volume: Eₑᵥ (see following Equation (5)).

Note that structure stabilization energy other than the above four types may be defined and included in the E_{stab}.

$${E}_{bl} = {\sum }_{i} {{K}_{b , i} ( {b}_{i} - {b}_{i}^{( 0 )} )}^{2} \qquad ( 2 )$$

$${E}_{ba} = {\sum }_{i} {{K}_{θ , i} ( {θ}_{i} - {θ}_{i}^{( 0 )} )}^{2} \qquad ( 3 )$$

$${E}_{da} = {\sum }_{i} \{ {K}_{ϕ , i}^{( 1 )} ( 1 - cos ( {ϕ}_{i} - {ϕ}_{i}^{( 0 )} ) ) + {K}_{ϕ , i}^{( 3 )} ( 1 - cos 3 ( {ϕ}_{i} - {ϕ}_{i}^{( 0 )} ) ) \} \qquad ( 4 )$$

$${E}_{ev} = {\sum }_{i} {\sum }_{j = i + 1} {{ϵ}_{ev} ( \frac{{d}_{ij}}{{r}_{ij}} )}^{β} \qquad ( 5 )$$

Equation (2) is an example of interaction energy related to bond length. In Equation (2), bᵢ is a bond length held by residue i and residue i+1, bᵢ⁽⁰⁾ is an average bond length, K_{b, i} is a constant (for example, 110.4 kcal/mol/Å²). Equation (3) is an example of interaction energy E_{ba} related to bond angle. In Equation (3), θᵢ is an i^{th} bond angle formed between two consecutive covalent bonds, θᵢ⁽⁰⁾ is an average bond angle, and K_{θ, i} is a constant (for example, 22.08 kcal/mol/Å²). Equation (4) is an example of interaction energy E_{da} related to dihedral angle. In Equation (4), φᵢ is an i^{th} dihedral angle defined by three consecutive covalent bonds, and φᵢ⁽⁰⁾ is an average dihedral angle. Moreover, Kφᵢ⁽¹⁾ is a constant (for example, 1.104 kcal/mol/Å²), and Kφᵢ⁽³⁾ is a constant (for example, 0.552 kcal/mol/Å²). Equation (5) illustrates an example of an interaction energy Eₑᵥ related to excluded volume. dᵢⱼ is an excluded volume dependent on residue i and residue j, rᵢⱼ is a Euclidean distance between the Cα atoms of residue i and residue j, εₑᵥ is a constant (for example, 0.6 kcal/mol), and β is a real number β≥1.

Moreover, as structure information for use as training data, the generation section 12 generates a coarse-grained model being coarse-graining a structure after the above correction. For example, as described above, the generation section 12 generates a coarse-grained model of a post-correction all-atom model coarse-grained at the Cα atom unit of each residue. Moreover, the generation section 12 extracts feature values related to the generated coarse-grained model, and reduces the dimensionality of explanatory variables. For example, the generation section 12 may extract feature values such as weighted atom-centered symmetry functions (wACSF), smooth overlap of atomic position (SOAP), and the like. Moreover, the generation section 12 may employ three-dimensional coordinates of each residue (Cα atom) configuring a protein as direct feature values. Appropriate feature values may be extracted corresponding to configuration of a machine learning model expressing an AI force field subjected to machine learning by the machine learning section 14, described later.

The machine learning section 14 employs the training data generated by the generation section 12 to execute machine learning of the AI force field for predicting an energy for an input structure. The AI force field is an example of a “first force field” of technology disclosed herein. The AI force field may, for example, be configured as a machine learning model such as high-dimensional neural network potentials (HDNNP), graph neural networks, or the like.

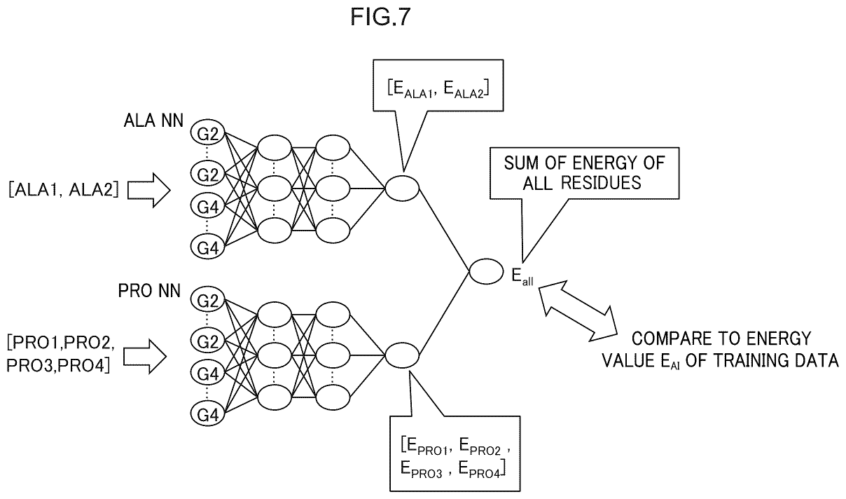

HDNNP are multiple neural networks for preparing molecular descriptors for each particle. For example, in cases in which HDNNP are applied in the present exemplary embodiment, as illustrated in FIG. 7, an AI force field is configured by a neural network for each type of amino acid contained in a protein. The example illustrated in FIG. 7 contains a neural network for alanine (ALA NN) and a neural network for proline (PRO NN). Feature values extracted for the structure of each amino acid residue are input to the input nodes indicated by G2 and G4. Note that G2 and G4 are input with feature values extracted using wACSF, with G2 envisaged as being input with a feature value based on inter-particle distance, and G4 envisaged as being input with a feature value based on inter-particle angle.

Energy values are output for each residue from each neural network. For example, energy values [E_{ALA1}, E_{ALA2}] are output from the ALA NN when input with respective feature values for two alanine residues [ALA1, ALA2]. Similarly, energy values [E_{PRO1}, E_{PRO2}, E_{PRO3}, E_{PRO4}] are output from the PRO NN when input with respective feature values for four proline residues [PRO1, PRO2, PRO3, PRO4]. An energy value Eₐₗₗ resulting from summing the energy values of each residue is output from the final output layer of the AI force field.

The machine learning section 14 compares the energy value Eₐₗₗ output from the AI force field against the energy value E_{AI} of the training data, and executes machine learning on the AI force field by updating parameters of the machine learning models configuring the AI force field to get the Eₐₗₗ to approach the E_{AI}.

The computation section 16 computes molecular dynamics of a coarse-grained model based on a hybrid force field resulting from combining the AI force field after machine learning by the machine learning section 14 by combining with an energy based on the coarse-grained model structure. The hybrid force field is an example of a “second force field” of technology disclosed herein. The hybrid force field E_{hybrid} is expressed by following Equation (6).

$${E}_{hybrid} = {E}_{AI} ( r ) + {E}_{stab} \qquad ( 6 )$$

The computation section 16 inputs a coarse-grained model structure (input structure r) to the AI force field and predicts an energy value E_{AI} (r). The computation section 16 computes E_{stab} based on the coarse-grained model structure. The computation section 16 then computes the hybrid force field E_{hybrid} according to Equation (6).

As described above, E_{stab} based on the all-atom model structure is excluded from the AI force field during machine learning. On the other hand, due to the force field during MD execution being a coarse-grained force field, E_{stab} based on the coarse-grained model structure is added to the energy value E_{AI} predicted by the AI force field. A difference between the energy based on the all-atom model used during machine learning and the energy based on the coarse-grained model used during MD execution is absorbed thereby, time evolution of the CG-MD is stabilized, and also unstable high energy states can be prevented.

The computation section 16 computes an acting force on each particle included in the coarse-grained model based on the hybrid force field E_{hybrid}, computes motion in unit time for each particle in response to the computed force based on the equations of motion, and updates the position of each particle after unit time. The computation section 16 simulates structural change of the coarse-grained model by repeatedly performing the above computation for each unit time with the coarse-grained model in which the positions of each particle have been updated.

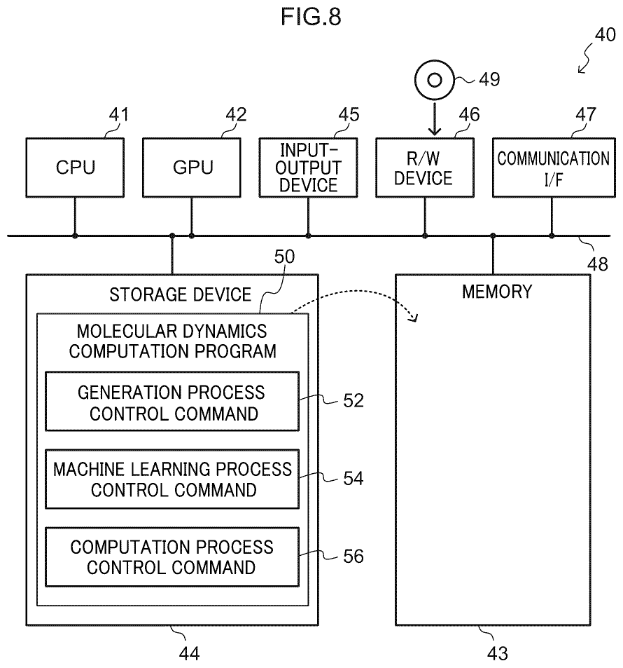

The molecular dynamics computation device 10 may, for example, be implemented by a computer 40 as illustrated in FIG. 8. The computer 40 includes a central processing unit (CPU) 41, a graphics processing unit (GPU) 42, memory 43 serving as a temporary storage area, and a non-volatile storage device 44. The computer 40 also includes an input-output device 45 such as an input device, display device, or the like, and a read/write (R/W) device 46 that controls reading of data from a storage medium 49 and writing data thereto. The computer 40 includes a communication interface (I/F) 47 connected to a network such as the Internet. The CPU 41, the GPU 42, the memory 43, the storage device 44, the input-output device 45, the R/W device 46, and the communication I/F 47 are all connected to each other through a bus 48.

The storage device 44 is, for example, a hard disk drive (HDD), solid state drive (SSD), flash memory, or the like. A molecular dynamics computation program 50 that causes the computer 40 to function as the molecular dynamics computation device 10 is stored on the storage device 44 serving as a storage medium. The molecular dynamics computation program 50 includes a generation process control command 52, a machine learning process control command 54, and a computation process control command 56.

The CPU 41 reads the molecular dynamics computation program 50 from the storage device 44, expands the molecular dynamics computation program 50 into the memory 43, and sequentially executes the control commands contained in the molecular dynamics computation program 50. The CPU 41 operates as the generation section 12 illustrated in FIG. 4 by executing the generation process control command 52. The CPU 41 operates as the machine learning section 14 illustrated in FIG. 4 by executing the machine learning process control command 54. The CPU 41 operates as the computation section 16 illustrated in FIG. 4 by executing the computation process control command 56. The computer 40 executing the molecular dynamics computation program 50 accordingly functions as the molecular dynamics computation device 10. Note that the CPU 41 executing the program is hardware. Part of the program may be executed by the GPU 42.

Note that functions implemented by the molecular dynamics computation program 50 may, for example, be implemented by a semiconductor integrated circuit, or more specifically by an application specific integrated circuit (ASIC), a field programmable gate array (FPGA), or the like.

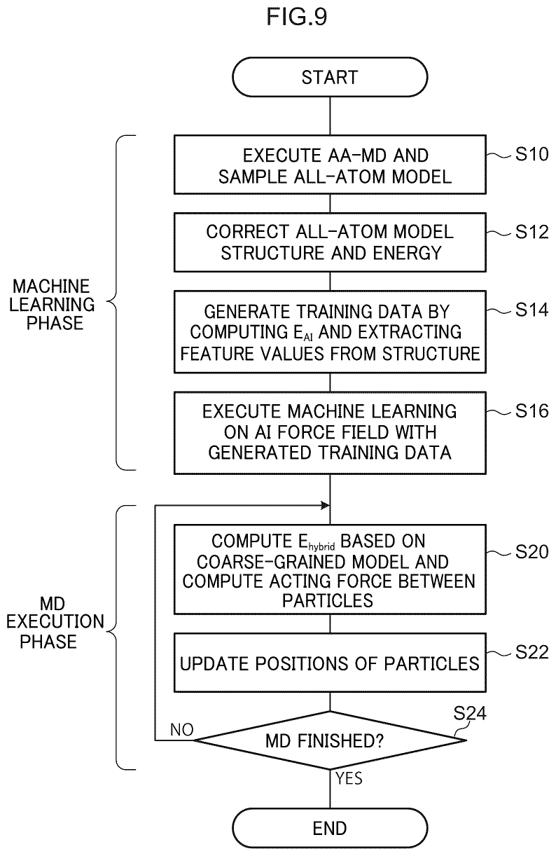

Next, description follows regarding operation of the molecular dynamics computation device 10 according to the present exemplary embodiment. The molecular dynamics computation device 10 executes the molecular dynamics computation processing illustrated in FIG. 9. The molecular dynamics computation processing includes a machine learning phase and a MD execution phase. Note that the molecular dynamics computation processing is an example of a molecular dynamics computation method of technology disclosed herein.

First description follows regarding the machine learning phase.

At step S10, the generation section 12 executes AA-MD and samples plural all-atom model structures and energies corresponding to these structures. Next, at step S12, the generation section 12 performs, on the structures and energies obtained at step S10, at least one correction selected from the group consisting of correction to stabilize energy, correction to minimize energy, and correction to average energy.

Next, at step S14, the generation section 12 computes the energy value E_{AI} according to Equation (1), and also extracts feature values related to the coarse-grained model structure resulting from coarse-graining the post-correction all-atom model, and generates training data including the EAT and the feature values. Next, at step S16 the machine learning section 14 uses the training data generated at step S14 to execute machine learning on the machine learning model expressing an AI force field for predicting energy for an input structure.

Next, description follows regarding the MD execution phase.

At step S20, the computation section 16 inputs a coarse-grained model structure (input structure r) to the AI force field and predicts the energy value E_{AI} (r), and also computes E_{stab} based on the coarse-grained model structure. The computation section 16 then uses the E_{AI} (r) and the E_{stab} to compute a hybrid force field E_{hybrid} according to Equation (6), and computes an acting force on each of the particles contained in the coarse-grained model based on the computed hybrid force field E_{hybrid}.

Next, at step S22, based on the equations of motion, the computation section 16 computes motion in unit time for each particle in response to the force computed at step S20, and updates the position of each particle after unit time. Next, at step S24, the computation section 16 determines whether or not to end MD execution such as by determining whether or not a predetermined simulation duration has been reached. Processing returns to step S20 when determined not to end, and the molecular dynamics computation processing is ended when determined to end MD execution.

As described above, the molecular dynamics computation device according to the present exemplary embodiment generates training data including a coarse-grained model structure resulting from coarse-graining an all-atom model sampled by molecular dynamics computation based on an all-atom force field, and including an energy corresponding to the all-atom model structure. The molecular dynamics computation device uses the generated training data to execute machine learning on the AI force field for predicting the energy of an input structure. Moreover, the molecular dynamics computation device computes molecular dynamics of the coarse-grained model based on the hybrid force field resulting from combining the AI force field that has been subjected to machine learning with the energy based on the coarse-grained model structure. The coarse-grained model MD is thereby executed based on the hybrid force field incorporating the AI force field based on the high accuracy all-atom model and the coarse-grained force field. In other words, the molecular dynamics computation device according to the present exemplary embodiment builds a coarse-grained force field that excludes arbitrary terms of a stabilized reference structure. In this manner, the force field applied during MD execution in the present exemplary embodiment differs from the related coarse-grained force field of structure base, and is not derived from the standpoint of being based on a reference structure (does not need a particular reference structure). This means that in the smooth force field accompanying coarse-graining, the sampling of molecular structures can be performed from a wide structure space without being constrained to reference structures. Therefore, efficient sampling of diverse molecular structures can be performed.

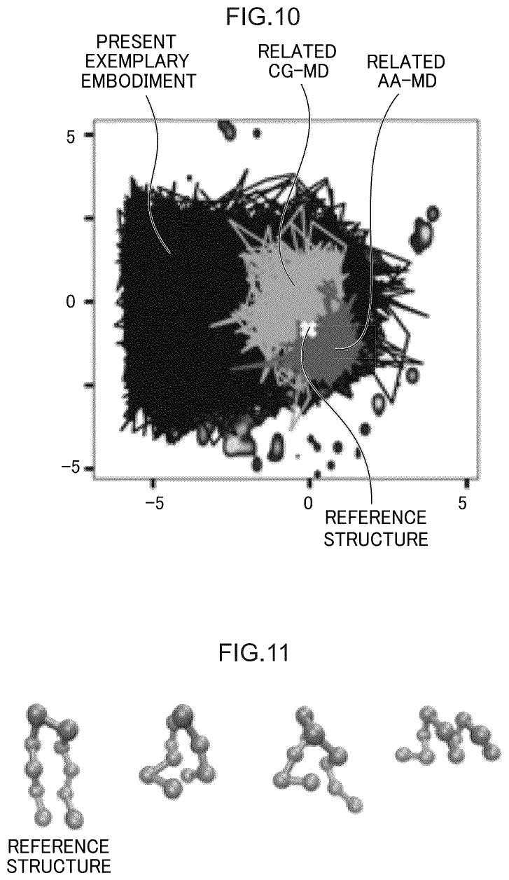

FIG. 10 illustrates a comparison of distributions of structures sampled by the present exemplary embodiment in principal component space, compared to distributions of related AA-MD or related CG-MD. In the present exemplary embodiment, sampling is performed over a wider range of structures than in related AA-MD or related CG-MD. Moreover, FIG. 11 illustrates an example of structures sampled in the present exemplary embodiment. The first structure on the left in FIG. 11 is a reference structure. As illustrated in FIG. 11, the present exemplary embodiment enables sampling of diverse structures without being constrained to reference structures.

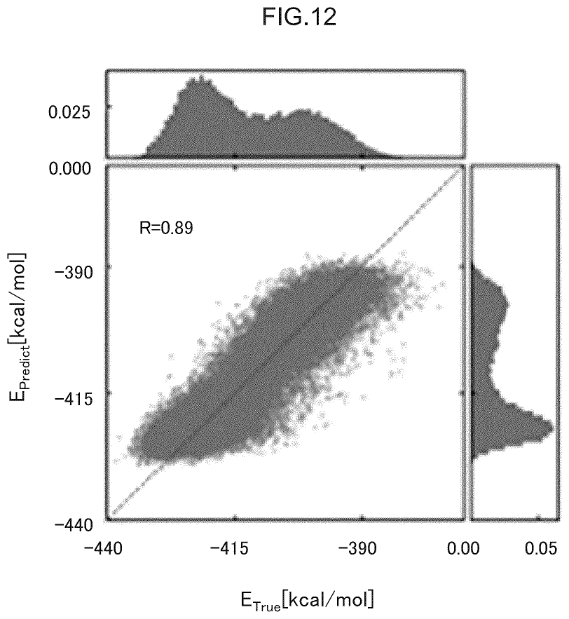

Moreover, in the present exemplary embodiment, as described above, due to employing the AI force field based on a high accuracy all-atom model, a higher prediction accuracy can be implemented than in related CG-MD. FIG. 12 illustrates correlations between energy predicted values E_{Predict} computed for sampled structures in the present exemplary embodiment and energy true values E_{True} for these structures. As illustrated in FIG. 12, a high correlation is seen between the predicted values and the true values (correlation coefficient=0.89), and it is apparent that a high prediction accuracy is obtained.

Note that in the exemplary embodiment described above, although a case has been described in which AI force field machine learning and execution of MD based on the hybrid force field are both executed on the same computer, there is no limitation thereto. For example, a machine learning device including the generation section and the machine learning section, and a molecular dynamics computation device including the computation section, may be implemented by different computers.

Moreover, although in the above exemplary embodiment the molecular dynamics computation program was pre-stored (installed) on the storage device, there is no limitation thereto. The program according to technology disclosed herein may be provided in a format stored on a storage medium such as a CD-ROM, DVD-ROM, USB memory, or the like.

An issue with all-atom molecular dynamics is the significantly high computation cost thereof. Coarse-grained molecular dynamics is accordingly proposed that computes molecular dynamics using a model resulting from coarse-graining an all-atom model. However, in cases in which simulation is executed by coarse-grained molecular dynamics and structure data is sampled, reference structures are given for structures held, and sampling of structures is performed based on a force field that includes arbitrary terms coming from these reference structures. There is accordingly an issue in that the reference structures are strongly stabilized, and it is difficult to sample diverse structures.

The technology disclosed herein enables arbitrary terms arising from a reference structure being stabilized to be excluded from the force field.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A non-transitory recording medium storing a program that is executable by a computer to perform a molecular dynamics computation process comprising:
executing machine learning of a first force field for predicting energy for an input structure using, as training data, a structure of a coarse-grained model resulting from coarse-graining an all-atom model sampled by molecular dynamics computation based on an all-atom force field and an energy corresponding to the all-atom model structure; and
computing molecular dynamics of a coarse-grained model based on a second force field obtained by combining the first force field that has been subjected to machine learning and an energy based on a coarse-grained model structure.

2. The non-transitory recording medium of claim 1, wherein the energy used as training data is an energy obtained by excluding an energy based on the all-atom model structure from a potential energy of the all-atom model.

3. The non-transitory recording medium of claim 1, wherein the energy based on the coarse-grained model structure is a structure stabilization energy.

4. The non-transitory recording medium of claim 1, wherein computing molecular dynamics of the coarse-grained model includes:
computing a force acting on each particle included in the coarse-grained model based on a potential energy of the coarse-grained model computed by taking an energy predicted by inputting a coarse-grained model structure to the first force field and adding an energy computed based on the coarse-grained model structure;
computing motions in unit time of each of the particles in response to the force based on equations of motion; and
updating positions of each of the particles after elapse of the unit time.

5. The non-transitory recording medium of claim 1, wherein the training data is generated by performing, on the sampled all-atom model and the energy corresponding to the all-atom model structure, at least one correction selected from the group consisting of correction to stabilize energy, correction to minimize energy, and correction to average energy.

6. A molecular dynamics computation method comprising:
by a processor,
executing machine learning of a first force field for predicting energy for an input structure using, as training data, a structure of a coarse-grained model resulting from coarse-graining an all-atom model sampled by molecular dynamics computation based on an all-atom force field and an energy corresponding to the all-atom model structure; and
computing molecular dynamics of a coarse-grained model based on a second force field obtained by combining the first force field that has been subjected to machine learning and an energy based on a coarse-grained model structure.

7. The molecular dynamics computation method of claim 6, wherein the energy employed as training data is an energy resulting from excluding an energy based on the all-atom model structure from a potential energy of the all-atom model.

8. The molecular dynamics computation method of claim 6, wherein the energy based on the structure is a structure stabilization energy.

9. The molecular dynamics computation method of claim 6, wherein computing molecular dynamics of the coarse-grained model includes:
computing a force acting on each particle included in the coarse-grained model based on a potential energy of the coarse-grained model computed by taking an energy predicted by inputting a coarse-grained model structure to the first force field and adding an energy computed based on the coarse-grained model structure;
computing motions in unit time of each of the particles in response to the force based on equations of motion; and
updating positions of each of the particles after elapse of the unit time.

10. The molecular dynamics computation method of claim 6, wherein the training data is generated by performing, on the sampled all-atom model and the energy corresponding to the all-atom model structure, at least one correction selected from the group consisting of correction to stabilize energy, correction to minimize energy, and correction to average energy.

11. A molecular dynamics computation device comprising:
a memory; and
a processor coupled to the memory, the processor being configured to execute processing, the processing including:
executing machine learning of a first force field for predicting energy for an input structure using, as training data, a structure of a coarse-grained model resulting from coarse-graining an all-atom model sampled by molecular dynamics computation based on an all-atom force field and an energy corresponding to the all-atom model structure; and
computing molecular dynamics of a coarse-grained model based on a second force field obtained by combining the first force field that has been subjected to machine learning and an energy based on a coarse-grained model structure.

12. The molecular dynamics computation device of claim 11, wherein the energy employed as training data is an energy resulting from excluding an energy based on the all-atom model structure from a potential energy of the all-atom model.

13. The molecular dynamics computation device of claim 11, wherein the energy based on the structure is a structure stabilization energy.

14. The molecular dynamics computation device of claim 11, wherein computing molecular dynamics of the coarse-grained model includes:
computing a force acting on each particle included in the coarse-grained model based on a potential energy of the coarse-grained model computed by taking an energy predicted by inputting a coarse-grained model structure to the first force field and adding an energy computed based on the coarse-grained model structure;
computing motions in unit time of each of the particles in response to the force based on equations of motion; and
updating positions of each of the particles after elapse of the unit time.

15. The molecular dynamics computation device of claim 11, wherein the training data is generated by performing, on the sampled all-atom model and the energy corresponding to the all-atom model structure, at least one correction selected from the group consisting of correction to stabilize energy, correction to minimize energy, and correction to average energy.
